(19) United States
(12) Patent Application Publication
(10) Pub. No.: US 2014/0211379 A1
(43) Pub. Date: Jul. 31, 2014

(54) TWO SIDED ELECTRICAL DISTRIBUTION CENTER

(71) Applicant: DELPHI TECHNOLOGIES, INC., Troy, MI (US)

(72) Inventors: THEODORE J. BOROWICZ, FLAT ROCK, MI (US); RUBEN AVILA, JUAREZ (MX); EDUARDO NUNEZ, EL PASO, TX (US); ERICK GONZALEZ, JUZREZ (MX); CRISTINA G. CUARON, EL PASO, TX (US); RAY N. RAUTIO, REDFORD, MI (US)

(73) Assignee: DELPHI TECHNOLOGIES, INC., Troy, MI (US)

(21) Appl. No.: 14/231,930

(22) Filed: Apr. 1, 2014

Related U.S. Application Data
(62) Division of application No. 13/091,304, filed on Apr. 21, 2011.

(51) Int. Cl. H05K 5/02

(52) U.S. Cl. CPC H05K 5/0239
USPC 361/642

(57) ABSTRACT

An electrical distribution center, bussed electrical center, or power distribution box includes a housing containing a plurality of electronic devices including a plurality of removable electronic devices. The housing further defines a plurality of openings on opposite side of the housing so that the removable electronic devices are accessible through at least one of the openings. The housing receivably couples at least one wire cable that is in electrical communication with the removable electronic devices. When the wire cable is coupled to the housing, the removable electronic device is accessed through one of the openings while the coupled wire cable remains attached to the housing. A relay and fuse electronic circuit arrangement and a fuse electronic circuit arrangement each effectively utilize the allotted packaging space within the housing while also conserving the use of circuit board traces.

### CROSS-REFERENCE TO RELATED APPLICATION

This application is a divisional application that claims the benefit under 35 U.S.C. §121 of U.S. patent application Ser. No. 13/091,304 filed Apr. 21, 2011, the entire disclosure of which is hereby incorporated herein by reference.

### TECHNICAL FIELD OF THE INVENTION

This invention relates to electrical distribution centers, and more particularly relates to electrical distribution centers for vehicular applications.

### BACKGROUND OF THE INVENTION

Electrical distribution centers are widely used in the automotive industry. Electrical distribution centers manage current flow to the many electrical components in electrical connection with the electrical distribution center generally from a common power source. Electrical distribution centers provide a centralized location for a population of electronic components including removable electronic components like removable relays, removable fuses, and the like. The challenge remains to centralize and fit the plethora of removable electronic components resulting from increased electrical content in a vehicle into an allotted volume of packaging space in the vehicle may not have similarly increased. It remains desirable to have accessibility to the removable electronic components if service to these removable components is required. The removable components may also be required to be accessible while the population of electronic components in the electrical center remains electrically powered by, and in electrical communication with wire cables attached to the electrical center. Providing the centralized location to package the removable electronic devices may also desirably free up packaging space elsewhere in the vehicle that might otherwise be used to package clusters of removable electronic devices which may also decrease the material, assembly, and serviceability costs associated with a multiple location packaging approach.

Thus, what is needed is a robust electrical distribution center that allows an increased number of removable electronic components to be packaged within that are easily accessed through a plurality of openings in the electrical distribution center regardless of the number of openings defined in the electrical distribution center while these electronic components disposed in the electrical distribution center remain electrically energized.

### BRIEF SUMMARY OF THE INVENTION

One aspect of the invention is to safely and reliably access an increased amount of electronic devices that also include an increased amount of removable electronic devices in an electrical current-carrying apparatus in a packaging space that generally has not increased in volume. Another aspect of the invention is packaging the increased amount of removable electronic devices in a manner so that the removable electronic devices are easily accessed by an operator using only the operator's hands. In yet another aspect, accessing any of the removable electronic devices while at least one wire cable remains electrically connected to the electrical devices of the apparatus is also desired. To this end, another aspect of the invention is the discovery of electronic device packaging arrangements that satisfactorily intersect all of these aforementioned aspects. One electronic device arrangement disposed in the apparatus includes two or more removable electronic devices that may be advantageously densely bundled together in a compact space where at least one of the electrical connections in the arrangement does not require the use of circuit board trace during the construction of the arrangement. An electronic fuse arrangement may also be advantageously densely bundled together while also being packaged within the apparatus in an area of the apparatus that opposes connector ports disposed on the apparatus. The connector ports of the apparatus receive wire cables that electrically communicate with the electronic devices of the apparatus. This fuse device arrangement, then, allows efficient use of the allotted space in the apparatus beneath the connector port. Based on the desire to have accessibility to any of the removable electronic devices by an operator without using a tool while the electronic devices remain in electrical communication to the at least one wire connector, and in accordance with one embodiment of the invention, an electrical current-carrying apparatus includes a housing containing a plurality of electronic devices including removable electronic devices that are disposed in the housing. The housing defines a plurality of openings so that the removable electronic devices are accessible through at least one of the plurality of openings. The housing is configured to receivably couple at least one wire cable so that the at least one coupled wire cable is in electrical communication with at least one electronic device in the plurality of electronic devices. When the at least one wire cable is receivably coupled to the housing and the at least one removable device needs accessed, the at least one removable electronic device is accessed through at least one of the plurality of openings while the at least one coupled wire cable remains attached to the housing.

Further features and advantages of the invention will appear more clearly on a reading of the following detailed description of the preferred embodiment of the invention, which is given by way of non-limiting example only and with reference to the accompanying drawings.

### BRIEF DESCRIPTION OF THE SEVERAL VIEWS OF THE DRAWING

The present invention will now be described, by way of example with reference to the accompanying drawings, in which:

FIG. 1 shows an electrical current-carrying apparatus that is a power distribution box disposed an engine compartment of a vehicle in accordance with an embodiment of the invention;

FIG. 2 shows a magnified view of the power distribution box of FIG. 1;

FIG. 3 shows electrical components disposed adjacent a first opening of the power distribution box of FIG. 2, with the removable cover removed;

FIG. 4 shows removable electrical components disposed adjacent a second opening of the power distribution box of FIG. 2, with the removable cover removed;

FIG. 5 shows a side view of the power distribution box of FIG. 2 being removed from a bracket secured in the engine compartment;

FIG. 6 shows accessing removable electrical components through the first and the second opening by flippingly moving the power distribution box of FIG. 2 about the at least one coupled wire cable that remains attached to the power distribution box;

FIG. 7 shows an electronic circuit arrangement disposable in the power distribution box of FIG. 2, and details thereof;

FIG. 8 shows a topical view electrical schematic diagram of the electronic circuit arrangement of FIG. 7;

FIG. 9 shows a removable fuse circuit arrangement disposed within an area of the power distribution box of FIG. 2 underlying the connector port of the power distribution box that receivably couples a wire cable;

FIG. 10 shows a method to access the removable devices through one of the plurality of openings defined in the apparatus of FIG. 1; and

FIG. 11 shows a method to operate the apparatus of FIG. 1 that includes at least one electrical circuit arrangement that has at least one axially-aligned electrical connection.

### DETAILED DESCRIPTION OF THE INVENTION

An electrical current-carrying apparatus may supply power and control electrical signals to various electrical systems in the vehicle such as ignition systems, anti-lock braking systems, fuel systems, and air conditioning systems. Such an electrical current-carrying apparatus in the automotive industry is appropriately named as an electrical distribution center, a bussed electrical center, or a power distribution box. These power distribution boxes may carry, or transmit hundreds of amperes of electrical current that is metered, or parsed out to different electrical components or systems. Such electrical components or systems may include and are not limited to heated seats, defrosters, windshield wipers, ignition starter cores and the like, that may operate in the vehicle through independent fuses or switched power electrical circuits. With the continued increase in electrical content of the vehicle, more electrical devices including removable electrical devices, require packaging somewhere within the vehicle space where packaging space for these removable devices is increasingly limited. For example, the volume to package a power distribution box in an engine compartment may be limited and constrained due to other physical structures that take up space within the engine compartment, such as shock towers, headlight assemblies, other engine components, and even the vehicle's exterior contour design shape. This packaging space, perhaps, may be even more constricted and limited in an engine compartment of the vehicle. Desirably, an under-hood power distribution box provides a central location for the collection of these removable electronic devices while also being located proximate electronic engine components that are electrically connected to the power distribution box. Co-location of other removable electronic components in electrical connection with electrical components or electrical systems external to the engine compartment may also be desirably located in the power distribution box.

The following terms used in this specification have the following definitions:

Access, Accessibility—This term refers to a removable electronic device that is disposed in the electrical current-carrying apparatus may be visually seen in the electrical current-carrying apparatus by an eye of an operator so that the removable electronic devices may be removed/replaced in the apparatus through the plurality of openings of the apparatus.

Double-ended terminal—A double-ended terminal has terminal ends where one terminal end is attachable to a terminal of one removable device and another terminal end is attachable to an opposing removable device. At least one terminal end of the double-ended terminal may also be attachable with a terminal that is part of a connector, which is for example, attached to a wire cable. Either terminal end of the double-ended terminal may be a male or female-type terminal. The male terminal may be a blade terminal. The double-ended terminal may also be soldered to the circuit board to provide further mechanical support for the double-ended terminal.

Electric-current carrying apparatus—An electrical current-carrying apparatus that experiences the movement of electrons through the apparatus that has a unit of measure in amperes.

Electronic device—An electronic device may be part of an electrical circuit or system that uses the principle of electron flow through the electronic device. For instance, electrical devices may be generally fixedly secured to a printed circuit board by being soldered to the printed circuit board. An electrical device may also be a removable electrical device that generally is not directly soldered to the printed circuit board so as to be more easily removed if the removable electronic device needs serviced to replace a faulty device. Examples of electrical devices may include resistors, capacitors, inductors, transistors, relays, fuses, and the like.

Footprint of an electronic device—The space created by an electronic device as occupied by the electrical device that has a size and a shape of an area that the electrical device occupies. If the electrical device is disposed on a printed circuit board adjacent to the circuit board the two-dimensional, surface area created on the printed circuit board by the disposed electronic device may be referred to as the electronic device's footprint. The footprint of an electrical device may also be that two-dimensional, surface area which is extended on to an external surface of the printed circuit board by a plane generally perpendicular to the surface of the circuit board of the electronic device located proximate the printed circuit board.

Removable electrical device—An electrical device that is removable is easily renewable. A renewable device may be readily restored to operation by replacement in its place of origin in an electrical circuit with a similar electronic device. Such a removable electronic device is generally not fixedly secured to a position in an electrical circuit, such as when directly soldered to a printed circuit board, but may require a non-soldering iron type tool such as a fuse puller, or pliers to remove/replace the removable electronic device from its place of origin in the electrical circuit. The tool would also need to fit through the plurality of openings in the electrical current-carrying apparatus to remove/replace the removable electronic device. Removable relay devices and removable fuse devices are typical removable electronic devices.

Tool—Anything held in the hand of an operator that assists the operator to access removable electronic devices through the plurality of openings of the electrical current-carrying apparatus. Examples of tools may be picks, screwdrivers, pliers, wrenches, et cetera. Once the removable electronic device is accessed through one of the plurality of openings, a tool may be used to remove/replace the removable electronic device through the plurality of openings of the electrical current-carrying apparatus.

Special Tool—Anything held in the hand of an operator that assists the operator to perform work. More specifically, a special tool formed in a manner so as to have a generally single purpose and keep other operators who do not possess the special tool from conducting the manual work. For example, special tools may generally prevent serviceability work to the electrical current-carrying apparatus in a vehicle except by an operator or service technician who possess and employ the use of the special tool during service to the electrical current-carrying apparatus.

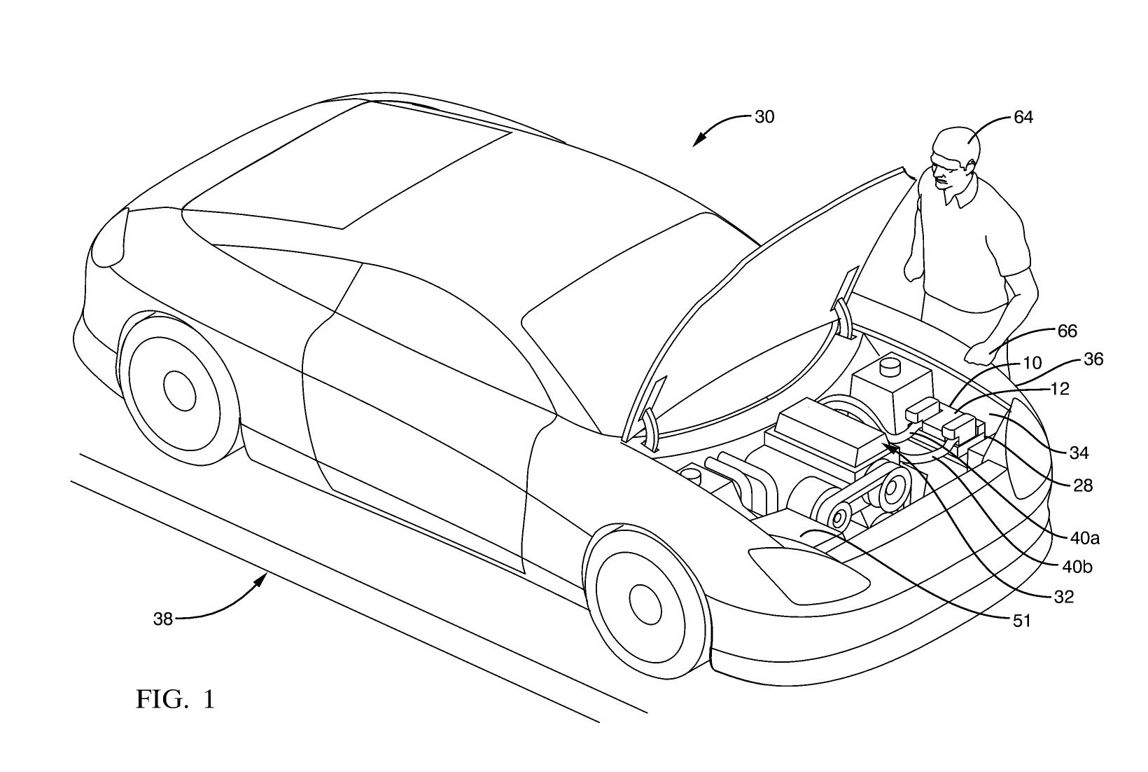

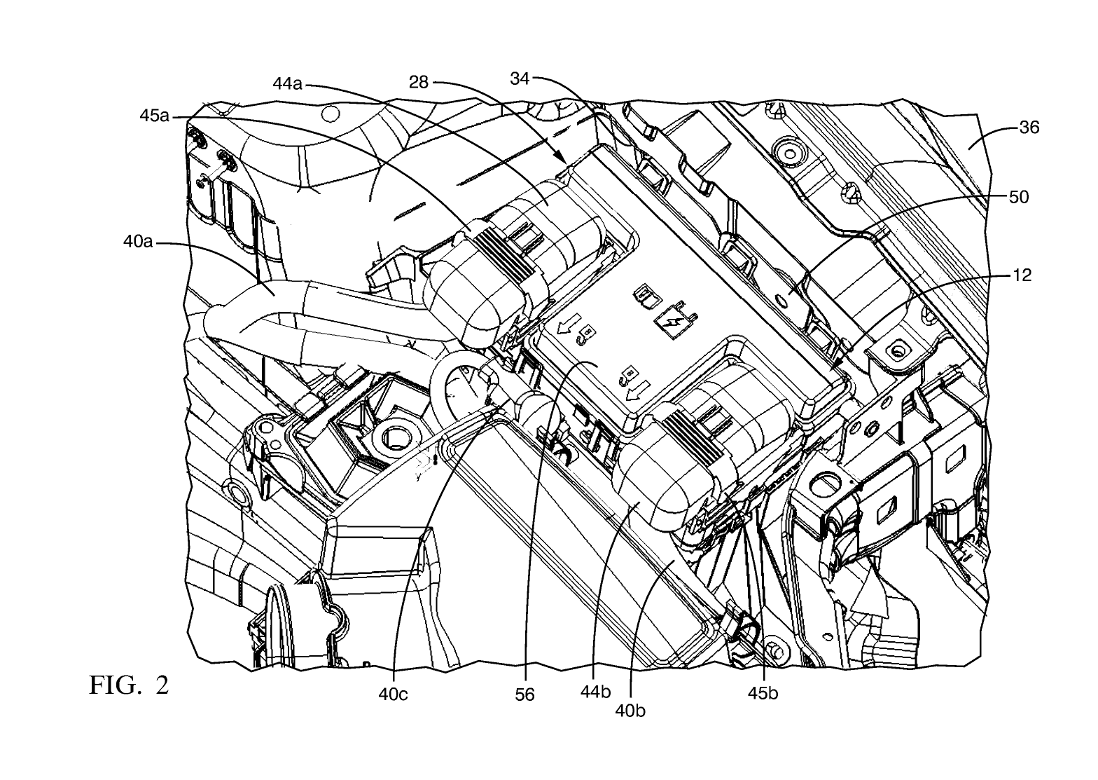

In accordance with a one embodiment of this invention, referring to FIGS. 1-11, an electrical-current carrying apparatus 10 is presented. Apparatus 10 is a power distribution box 12 that includes a plurality of electronic devices 14 at least some of which are removable electronic devices 16. Referring to FIG. 2, power distribution box 12 has a rectangular shape. Housing 18 is further formed from an upper housing 19 attached to a lower housing 21. Upper and lower housing 19, 21 are attached together by a plurality of housing lock tabs 52 that surround a perimeter of power distribution box 12. Tabs 52 are mechanically press-fit by a machine and are not meant to be opened by using only the hands of an operator 64. Tabs 52 may require a special tool to actuate tabs 52 and separate upper housing 19 from lower housing 21.

Housing 18 of apparatus 10 includes at least a first housing wall 20 formed in upper housing 19 and a second housing wall 22 formed in lower housing 21. Second housing wall 22 is opposite first housing wall 20. First wall 20 defines at a first opening 24 and second wall 22 defines a second opening 26. Housing 18 may be formed by injection molding by methods known in the molding arts. First and second openings 24, 26 provide accessibility to remove and renew any of the plurality of removable electronic devices 16 through first and second openings 24, 26 external to housing 18.

Power distribution box 12 is associated with a power distribution system 28 in vehicle 30 disposed in an engine compartment 32 of a vehicle 30 that includes a hydrocarbon fuel engine. Power distribution system 28 at least further includes the wiring and electrical connections disposed in vehicle 30 that interface with power distribution box 12. Alternately, the powertrain of the vehicle may be operated, or driven by an electric motor or a combination of an electric motor and a hydrocarbon fuel engine typically known as a hybrid vehicle. The hybrid vehicle may be a plug-in electric vehicle where a power supply cord is coupled to the vehicle to electrically charge the battery of the vehicle. Still yet alternately, the power distribution box may be located anywhere in the vehicle, such as perhaps suitably being disposed in the trunk or rear cargo area of the vehicle. Power distribution box 12 is disposed along an exterior wall 34 of engine compartment 32 adjacent an exterior wall 34 of vehicle 30. Vehicle 30 is disposed on a generally planar ground surface 38. First wall 20 is generally remote from ground surface 38 in a direction generally perpendicular to ground surface 38 and second wall 22 is intermediate first wall 20 and ground surface 38. First wall 20 and second wall 22 are generally parallel with ground surface 38.

Referring to FIGS. 2, 3, and 9, wire conductors 41 disposed in wire cables 40a, 40b terminate and are attached in corresponding mating connectors 48 that are coupled to, and received by respective connector ports 42 along first wall 20 of power distribution box 12. Alternately, any number of connector ports may be disposed on the power distribution box and receive any number of connectors that are attached to any number of wire cables. Wire cable 40c connects a power supply source to power distribution box 12 terminating in a lug (not shown) that is fastened to a mechanical bolt 51 disposed on power distribution box 12 adjacent housing 18. This power supply source provides a power source 86 for power distribution box 12 and power source 86 may take the form of a power bus bar disposed within the power distribution box. For example, the power supply source may be directly supplied from the B+, or positive terminal of the battery of the vehicle. Alternately, a power source supplied to the power distribution box may be fuse protected. Still yet alternately, the power supply source from the battery may be indirectly or directly supplied to the power distribution box through the wire cables or in any other possible configuration as required for a specific electrical application where the power distribution box may be employed. In another embodiment, the power supply source for the power distribution box may be supplied to the power distribution box through other electronic components, modules, or systems disposed in the vehicle.

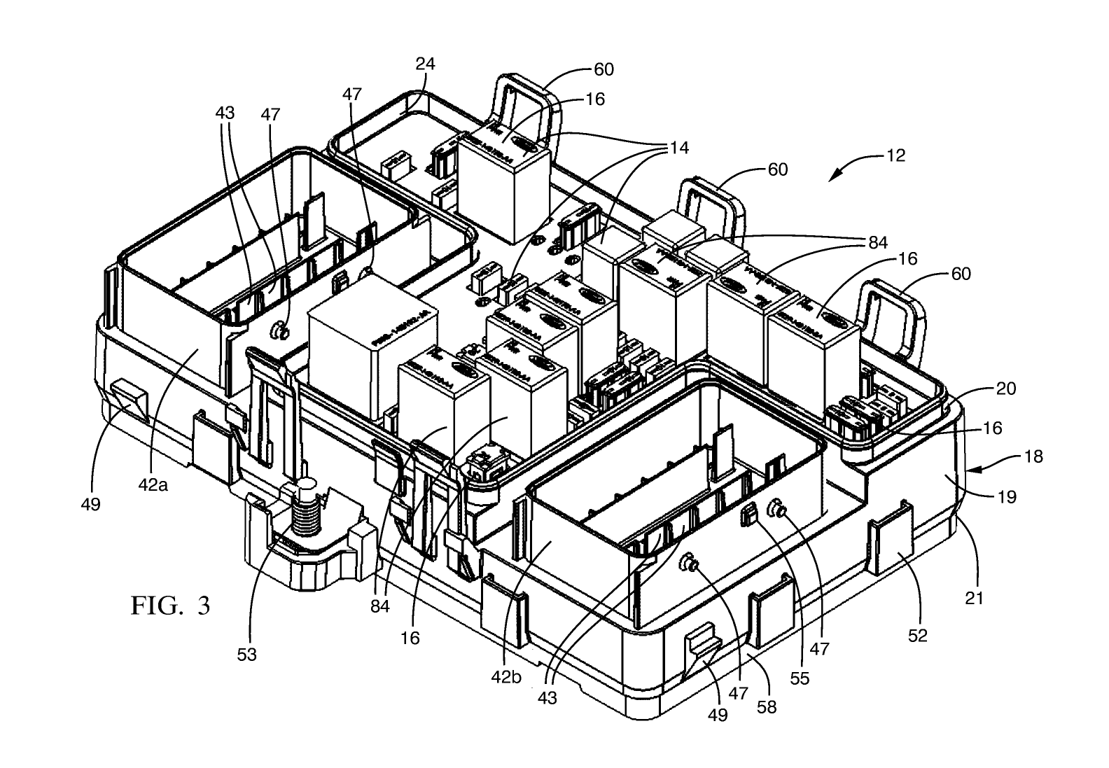

A plurality of wire cable connector covers 44a, 44b attach with respective coupled connectors 48 to overlie connector 48 and connector port 42 when connectors 48 are attached to connector ports 42. Covers 44 provide splash-proof protection from environmental elements, such as water, from penetrating in power distribution box 12. Covers 44a, 44b attach mating connectors 48 with respective manually releasable latches 45a, 45b to secure mating connectors 48 and covers 44 to connector mechanical lever assist pins 47 projecting from connector ports 42. Using at least one hand 66, the operator 64 may engage latches 45 to release covers 44 and expose first and second openings 24, 26. Covers 44 are distinct from connectors 48 where connectors 48 also include a seal (not shown) that further keep environmental elements from entering power distribution box 12 or terminals at connector ports 42 when covers 44 are attached with connector ports 42. As covers 44 are void of hinges, a simpler mold may be constructed to injection mold covers 44 which may decrease manufacturing costs to construct the covers. Alternately, the covers covering the openings may be hinged covers and the hinge may communicate with the housing. Lever lock actuation tab 55 provides a way to unlock securing latches 45 from pins 47 and release connectors 48 and corresponding wire cables 40 from power distribution box 12. Referring to FIG. 3, connector ports 42a, 42b each include electrically-conductive terminals 43 that electrically interface with electrically-conductive terminals in connectors 48 that are electrically connected to wire conductors 41 of respective wire cables 40a, 40b. Thus, when wire cables 40a, 40b, 40c are attached with power distribution box 12, wire cables 40a, 40b, 40c electrically interface and have electrical conductivity with the electronic circuits and at least one electronic device in plurality of electronic devices 14 disposed in power distribution box 12 with electrical components and systems disposed on vehicle 30. The connector ports may be sized to include any number of terminals as is required for a specific electrical application.

And being disposed in along first wall 20, wire cables 40 are positioned to form a semi-circular shape that depends away from first wall 20 of power distribution box 12 to form a natural run-off, gravity-draining drip-loop mechanization. This drip-loop mechanization of wire cables 40 may be useful to prevent further environmental elements from possible intrusion towards housing 18 that provides for a more robust power distribution box 12 as the environmental elements will wick harmlessly in a downward direction along wire cables 40 away from power distribution box 12. First and second openings 24, 26 provide accessibility to remove and renew any of removable electronic devices 16 through plurality of first and second openings 24, 26 in housing 18 while wire cables 40 remain coupled to apparatus 10 and remain in electrical communication with at least one electrical device in plurality of electronic devices 14. Coupled wire cables 40 are useful to ensure electrical operation of removable electronic devices 16 disposed in apparatus 10 that may be readily diagnosable by an operator 64. If wire cables 40 are unconnected from apparatus 10, apparatus 10 may at least be partially or totally electrically inoperative such that electronic devices 14 may undesirably not be electrically diagnosable by operator 64. For example, the operator may be an owner of vehicle 30 that may service removable electronic devices 16. In another example, operator 64 may also be a service technician or a vehicle assembly plant technician.

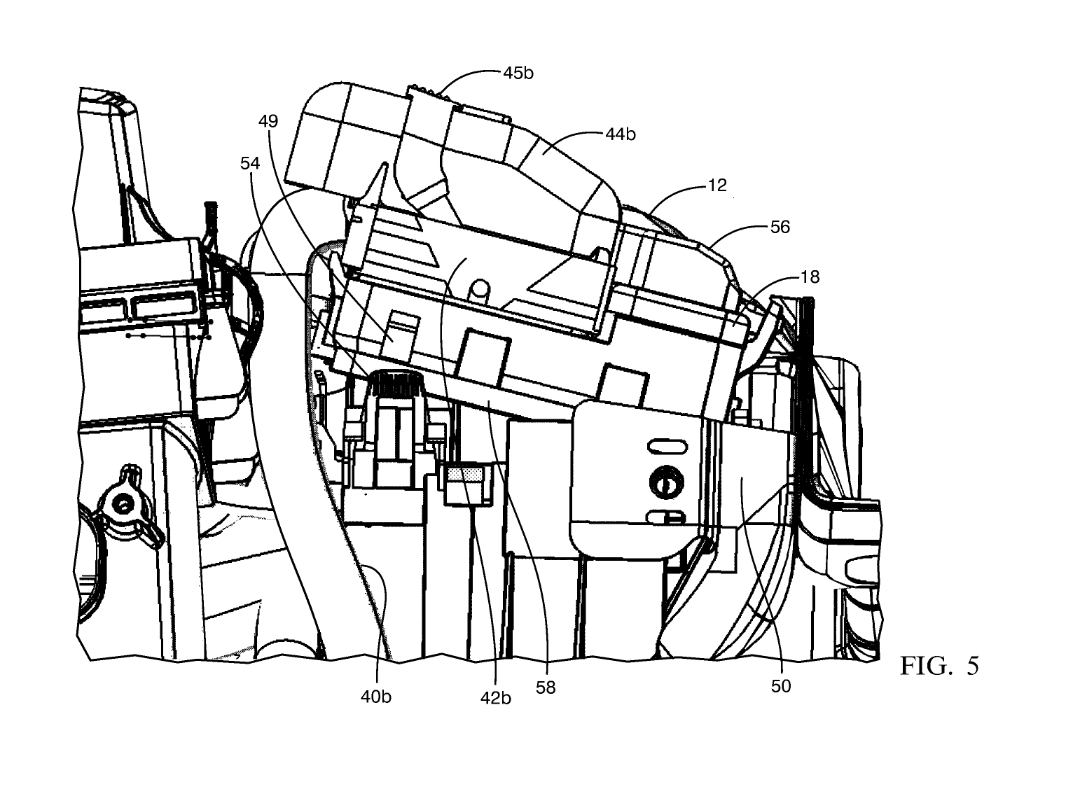

Power distribution system 28 also includes a bracket 50 and power distribution box 12 is removably coupled to bracket 50. Referring to FIGS. 2 and 5, power distribution box 12 is receivably coupled and secured to bracket 50 by a finger-actuated tabs 54 disposed on bracket 50 that are received by in-board lock wedges 49 disposed along an exterior surfaces of upper housing 19. Upper housing 19 of power distribution box 12 is formed of a first dielectric material and lower housing 21 is formed of a second dielectric material different from the first dielectric material. Alternately, the upper and lower housing of the power distribution box may be formed of plastic material where additives may be added for increased temperature resistance or strength. Still yet alternately, the upper and lower housing may be constructed from the same material. In one embodiment the upper and lower housing may be formed from a 14% glass filled plastic material. Bracket 50 may also be injection molded and may be formed of any of the materials use to form housing 18 as previously discussed herein. Alternately, bracket may be formed from any type of plastic material with or without additives for strength improvement or for enhanced performance under high or low operating temperature. Preferably, upper and lower housing 19, 21 are formed from any dielectric material that may be application specific. Upper housing 19 may be constructed of a material so that the mechanical forces needed to attach connectors 48 of the wire cables 40 to connector port 42 will not cause damage to cams disposed on connector ports 42 with repeated mating of connectors 48 of wire cables 40. Connector 48a of wire cable 40a is keyed to fit connector port 42a and the connector (not shown) of wire cable 40b is keyed to fit connector port 42b.

First and second walls 20, 22 have a parallel, spaced apart relationship. First and second openings 24, 26 correspondingly have a similar parallel relationship. As viewed looking into engine compartment 32, power distribution box 12 has a rectangular shape as best illustrated in FIG. 2. The shape of first opening 24 forms a T-shape, with the T-shape being further formed and bounded as such by connector ports 42. The shape of second opening 26 does not mirror the T-shape of first opening 24, but rather is generally the rectangular shape of power distribution box 12. Thus, the surface area to access removable electronic devices 16 is greater through second opening 26 than through first opening 24. Alternately, the openings disposed in the housing may be any geometrical shape and the shapes used for the plurality of openings on the power distribution box may be dictated by the electrical application or be orientation specific.

A first removable cover 56 is configurable to cover and fit first opening 24 and second removable cover 58 is configured to cover and fit second opening 26. First and second covers 56, 58 are formed of a similar material as that of upper and lower housings 19, 21, as previously described herein. The different shapes of first and second openings 24, 26 ensure first and second covers 56, 58 only fit the first or second opening 24, 26 in a single orientation. First and second covers 56, 58 prevent undesired environmental elements, such as water, dirt, and engine lubricants like oil and grease, from entering housing 18 through first and second opening 24, 26. First and second covers 56, 58 include clips 60 for snap-fitting covers 56, 58 to clips 60 disposed on housing 18 adjacent first and second openings 24, 26. Thus, first and second covers 56, 58 are individually removably coupled, or attached to housing 18. Referring to FIG. 2, markings on first and second covers 56, 58 may be employed to assist operator 64 to open first and second covers 56, 58 and assist operator 64 in removable electronic device identification. These visible markings may be inscribed on the external outward surface of these removable covers by being molded, laser etched, pad printed, or screen printed. Alternately, visible markings may be included on the opposite, or inside internal portion of the removable covers that face inward the power distribution box when attached to the power distribution box. The T-shape of first removable cover 56 ensures removable first cover 56 is replaced to cover first opening 24 in a correct, single orientation. Multiple tabs orientated about a peripheral edge of second cover 58 ensure second cover 58 is replaced to cover second opening 26 in a correct, single orientation. First and second covers 56, 58 are removable by an operator without the use of a tool (not shown) or a special tool, preferably only using at least one hand 66 of operator 64. For instance, the tool may be a screwdriver, a metal pick, pliers, wrenches, or one the many special tools used in the automotive industry, and the like. Removing and attaching first and second covers 56, 58 by using at least one hand 66 of operator 64 saves time in accessing the removable electronic devices as operator 64 does not also need to remember to procure tools or special tools. Special tools generally also have an undesired cost incurred to procure the special tool. Power distribution box 12 may be manipulated, removed, or attached to bracket 50 with only using at least one hand 66 of operator 64 with no tool or special tool being required.

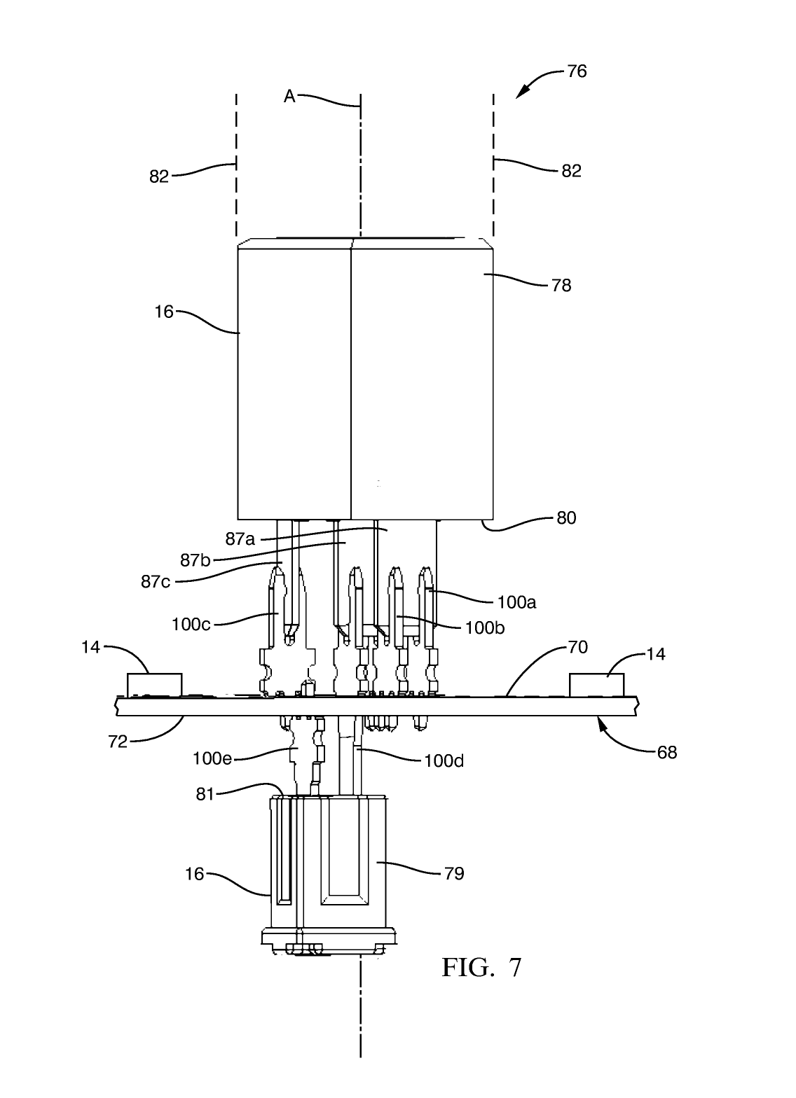

Referring to FIGS. 7-9, housing 18 of power distribution box 12 includes at least one printed circuit board 68 disposed in housing 18. Circuit board 68 is generally parallel to ground surface 38 intermediate first and second opening 24, 26. Circuit board 68 is also at least a 6-layer printed circuit board. Alternately, the circuit board may have any orientation within the housing of the power distribution box and be formed of any number of circuit board layers. Circuit board 68 is disposed in power distribution box 12 by being sandwiched, or trapped between upper and lower housing 19, 21 during construction of power distribution box 12 such that upper and lower housings 19, 21 retain and mechanically stabilize circuit board 68 in power distribution box 12. Alternately, circuit board 68 may be fastened in housing using any suitable fastener where the housing is preferably constructed to receive the fasteners. Plurality of electronic devices 14 are disposed on, or communicate in some manner with circuit board 68 with a number of parts being soldered to circuit board 68 before power distribution box 12 is constructed. Circuit board 68 may be formed from any suitable material, such as FR4 material, as is known in the electrical arts.

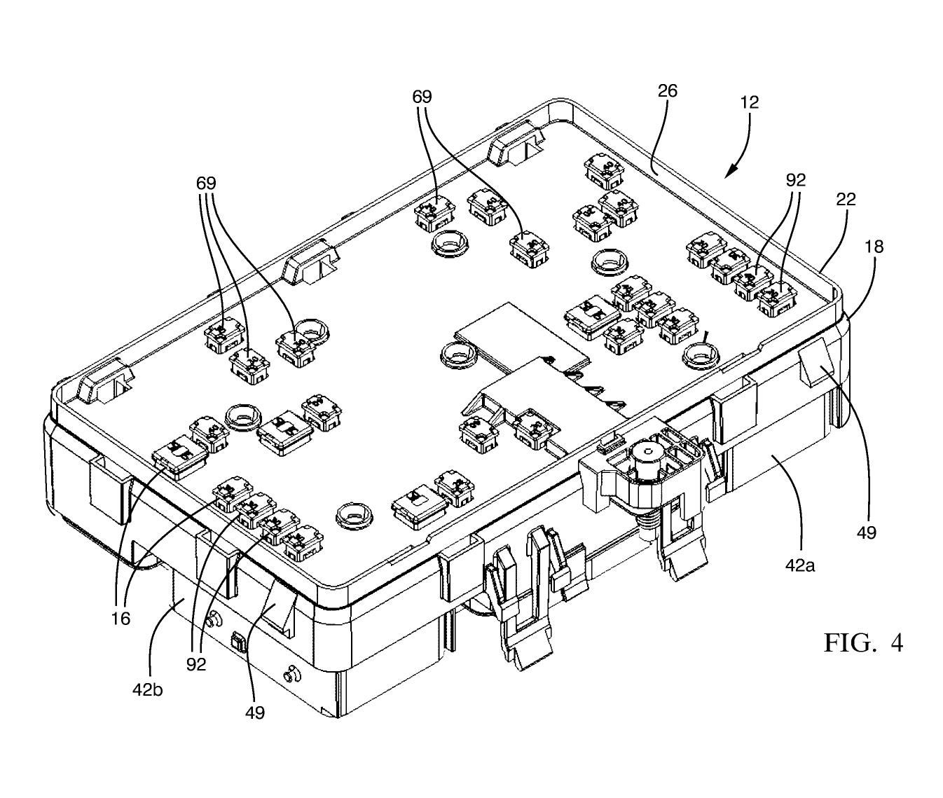

Circuit board 68 has a first external surface 70 and a second external surface 72 opposing first external surface 70. Circuit board 68 as a rectangular shape similar to that of power distribution box 12. Alternately, the circuit board may be any geometric shape. The circuit board may also comprise multiple circuit boards that are electrically connected in either parallel planes or disposed at adjoining, opposing, or perpendicular angles. Referring to FIG. 4, electronic devices 14 disposed proximate second surface 72 adjacent second opening 26 are only removable fuse devices 69. Alternately, any type of removable electronic device may be disposed within the housing of the power distribution box adjacent the first and the second opening. Still yet alternately, any electronic device may be disposed on or about the circuit board adjacent either the first or the second opening. Circuit board 68 includes circuit board trace 74 disposed on circuit board 68 that electrically interconnects at least a portion of electronic devices 14 that form electronic circuits in power distribution box 12. Preferably, circuit board trace 74 is formed of copper alloy material and the copper alloy material that has a generally high mass density. A power source supplied for circuit board 68 and plurality of electronic devices 14 is received via interface of bolt 51 with attachment of wire cable 40c thereat, as previously described herein. For example, the power source may be electrically transmitted within the power distribution box using a power bus bar formed by the circuit board trace on the circuit board, or using an electrically-conductive wire conductor or a formed electrically-conductive metal piece, and the like.

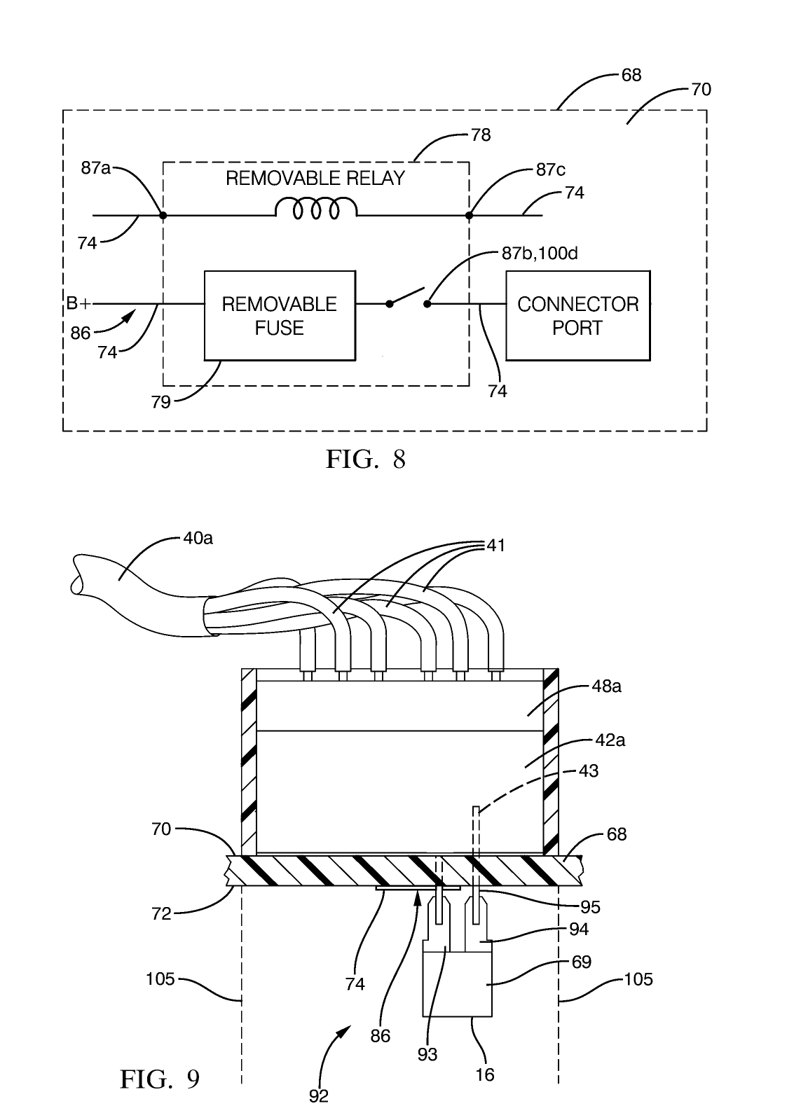

Referring again to FIGS. 7-8, at least one electronic circuit arrangement 76 disposed in housing 18 of power distribution box 12 and in communication with circuit board 68 includes at least a first, or removable relay device 78 and a second, or removable fuse device 79 among removable electronic devices 16 disposed in power distribution box 12. Removable relay device 78 is disposed along a longitudinal axis A and removable fuse device 79 is axially spaced apart from and opposed to removable relay device 78 with circuit board 68 disposed intermediate removable relay device 78 and removable fuse device 79. Thus, removable relay device 78 is axially in-line with removable fuse device 79. Removable relay device 78 is disposed proximate first surface 70 of circuit board 68 adjacent first opening 24 and removable fuse device 79 is disposed proximate second surface 72 of circuit board 68 adjacent second opening 26. Removable relay device 78 includes male blade terminals 87a, 87b, 87c that face first surface 70 of circuit board 68. Terminals, 100b, 100c, 100d, 100e communicate with circuit board 68. Terminals 100a, 100b, 100c have female terminations that receive male blade terminals 87a, 87b, 87c of removable relay device 78. Terminal 100e is in electrical and mechanical communication with circuit board 68 and with removable fuse device 79. Terminal 100d is a double-ended terminal as described above that passes through circuit board 68 and electrically communicates with removable fuse device 79 and has a female termination that receives and electrically connects with male blade terminal 87b. Terminal 100d is soldered to circuit board 68 in a manner that does not include circuit board trace and the soldered terminal 100d is not in connection with circuit board trace. Thus, terminal 100d of removable fuse device 79 is axially aligned with blade terminal 87d of removable relay device 78 and forms the direct axial electrical connection between the removable relay device 78 and the removable fuse device 79. Electronic circuit arrangement 76 is in electrical communication with either wire cable 40a or 40b, or a combination of 40a and 40b. The direct axial electrical connection between removable relay device 78 and removable fuse device 79 extends through circuit board 68 so as to not use circuit board trace. As previously described herein, reduction in the amount of circuit board trace results in power distribution box 12 having decreased weight, or mass as a result of reduction of copper material in the power distribution box that may allow for desired increased fuel efficiency for vehicle 30. Additionally, a reduction of copper material my advantageous realize a cost reduction to construct the circuit board. Alternately, the removable relay and fuse devices may have any number of connections that communicate with the circuit board, but still maintain the direct axial connection. Alternately, the fuse or the relay device may have any number of terminals that may be male or female mating to corresponding female or male terminals that are in communication with the circuit board while retaining the axially aligned terminal that directly electrically connects at least a portion of the two removable devices.

The removable relay device 78 includes a relay device footprint 80 and the removable fuse device 79 includes a fuse device footprint 81. Relay device footprint 80 of the removable relay device 78 defines a plane 82 that extends in a direction generally perpendicular to first and second surfaces 70, 72 of circuit board 68 where at least a portion of fuse device footprint 81 of removable fuse device 79 disposed proximate second surface 72 lies within plane 82. Referring to FIG. 7, a substantial portion of the fuse device footprint 81 of removable fuse device 79 lies within plane 82. Alternately, the footprint of the removable fuse device may lie completely within the footprint of the removable relay device. Still yet alternately, the footprint of the second removable device may lie completely within the footprint of the first removable device.

Referring to FIG. 3, when at least one electronic circuit arrangement 76 includes more than one electronic circuit arrangement 76, a group 84 of arrangements is formed. Group 84 may be disposed adjacent the connector ports or anywhere in the power distribution box. Each electronic circuit arrangement 76 in group 84 is in communication with circuit board 68 and has the respective axial electrical connection as previously described herein. Each electronic circuit arrangement 76 in group 84 is also connected to a power source 86 received from mechanical bolt 53 through attached wire cable 40c, as also previously described herein. This useful electrical circuit arrangement results effectively utilizes space in power distribution box 12 while also attaining desired material savings for power distribution box 12 in that circuit board trace is not required for axially aligned terminal 100d as shown in FIG. 7. As previously described herein, less printed circuit board trace results in decreased material savings and decreased mass that may allow for increased fuel efficiency of vehicle 30. Referring to FIG. 11, using power distribution box 12 that includes at least one electrical circuit arrangement having at least one axially-aligned electrical connection is step 201 in method 200.

Referring to FIG. 9, power distribution box 12 also includes a portion of removable electronic devices 16 that are removable fuse devices 69. At least one removable fuse device 69 in the portion of removable fuse devices 69 forms at least one fuse circuit arrangement 92. Removable fuse device 69 of fuse circuit arrangement 92 has an input 93 and an output 94. Input 93 is an input terminal of removable fuse device 69 which is connected to power source 86 in power distribution box 12. Output 94 is an output terminal of removable fuse device 69. Output 94 is connected with an electrically-conductive connecting terminal 95 and extends through circuit board 68 into connector port 42. Terminal 95 is a double-ended terminal. One end of terminal 95 is terminal 43 associated with connector port 42. The other end of terminal 95 fits output 94 of removable fuse device 69 of fuse circuit arrangement 92. Thus, the direct electrical connection using terminal 95 does communicates with circuit board 68 in a manner that does require the use of circuit board trace. Terminal 95 may be soldered to circuit board 68 to provide further mechanical support for terminal 95. Fuse circuit arrangement 92 is packaged underneath respective connector ports 42a, 42b to effectively use this space in power distribution box 12. Thus, power distribution box 12 may advantageously be able to fit more removable devices in a specified volume of space. Connector port 42a defines a plane 105 perpendicular to first and second surfaces 70, 72 of circuit board 68 such that at least a portion of removable fuse device 69 of fuse circuit arrangement 92 is disposed in plane 105. In one embodiment, this fuse arrangement may be utilized upwards of 8 times in the power distribution box and packaged beneath the connector ports to effectively use this packaging space while also not using circuit board trace to connect the respective outputs to separate terminals of the connector ports. Alternately, any number of fuse electronic arrangements may be packaged underlying the connector ports which may only be further limited by the amount of space disposed beneath the connector ports in combination with the ingenuity and creativity of the artesian in the electrical distribution center arts to fit them within this space. Using less circuit board trace may result in a power distribution box having lower mass which may translate into increased fuel efficiency for the vehicle.

Power distribution box 12 is not in use in vehicle 30 when wire cable 40c is not connected to bolt 51 of power distribution box 12. Power distribution box 12 is also not in use in vehicle 30 if wire cable 40c is connected to bolt 51 and both wire cable 40a and wire cable 40b are not connected to power distribution box 12.

Power distribution box 12 is partially in use in vehicle 30 if wire cable 40c is connected to bolt 51 of power distribution box 12 and either wire cable 40a is connected to connector port 42a or wire cable 40b is connected to connector port 42b. When one of the wire cables 40a, 40b is connected to power distribution box 12 and the other one of the wire cables 40a, 40b is not connected to power distribution box 12, power distribution box 12 may partially electrically operate dependent on the electrical connections obtained through the connected wire cable.

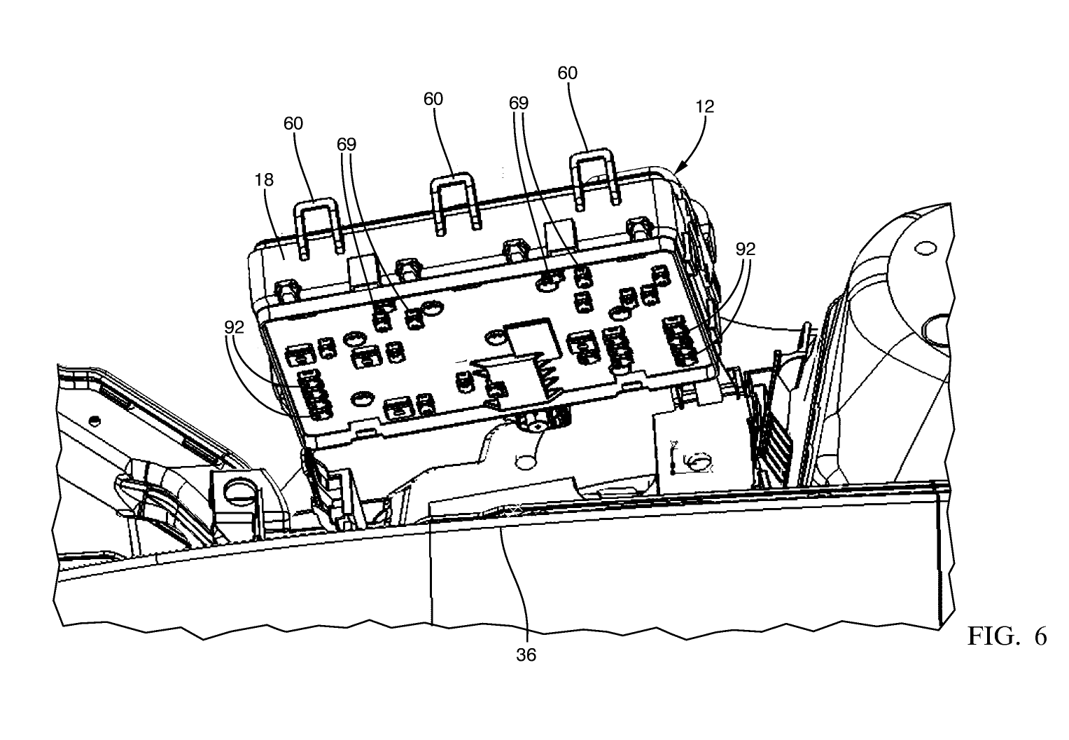

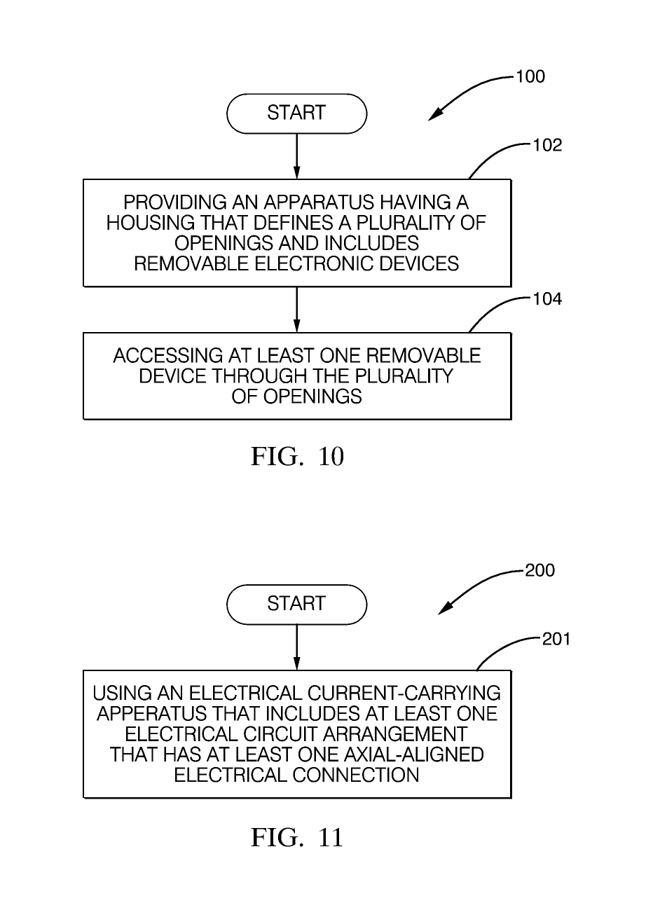

Power distribution box 12 is completely in use when wire cables 40a, 40b, 40c in vehicle 30 are respectively electrically connected to connector ports 42a, 42b and to bolt 51 of power distribution box 12. Referring to FIG. 10, providing power distribution box 12 is step 102 of method 100. If at least one removable electronic device 16 needs accessed through plurality of first and second openings 24, 26, for example when a removable electronic device 16 is deemed inoperative, removable electronic device 16 is accessed through one of first and second openings 24, 26 of power distribution box 12 while wire cables 40 remain attached to power distribution box 12 and electrically connect with at least one electronic device in plurality of electronic devices 14. Referring to FIG. 11, accessing at least one removable electronic device 16 through at least one of the plurality of first and second openings 24, 26 external to housing 18 is step 104 of method 100. Gaining access to at least one of the openings in the plurality of first and second openings 24, 26 of power distribution box 12 is a process. When power distribution box 12 is coupled in bracket 50, the process begins when power distribution box 12 is initially physically touched by at least one hand 66 of operator 64. The process from the initial touch to accessing at least one removable electronic device 16 through at least one of the plurality of first and second openings 24, 26 by operator 64 external to housing 18 is achieved, or attained by using at least one hand 66 of operator 64. Thus, attaining access to first and second openings 24, 26 is accomplished using only hands 66 without having to use a tool. The process may be even more noticeable when removable fuse devices 69 needs to be accessed through second opening 26. This requires power distribution box 12 to be removed from bracket 50 and be moveable about wire cables 40 by operator 64 to access either the first or second opening 24, 26. Removable first and second covers 56, 58 covering first and second openings 24, 26 may be removed from first and second openings 24, 26 by the hands 66 of operator 64 by engaging respective latches 54. Wire cables 40 are sufficiently long, or have sufficient length even when coupled to power distribution box 12, so that when removable electronic devices 16 adjacent the first opening 24 require access, power distribution box 12 is freely movable about coupled wire cables 40 so that first opening 24 is positioned to face operator 64. If removable electronic devices 16 adjacent second opening 26 require access by operator 64, second opening 26 is accessible to operator 64 when power distribution box 12 is movingly flipped relative to first opening 24 about coupled wire cables 40 so that second opening 26 visually faces operator 64. Moving flipping power distribution box 12 is a generally rotational movement about the coupled wire connectors, as best illustrated in FIG. 6. Additionally, accessing at least one removable electronic device 16 adjacent at least one of the first and second openings 24, 26 is achieved by operator 64 being disposed in a single stationary position adjacent the engine compartment 32, as best illustrated in FIG. 1. This is a very useful feature for operator 64 as removable electronic devices 16 are accessible without operator 64 having to establish multiple standing or other type of body positions to access removable electronic devices 16 which desirably reduces access and overall service time to service removable electronic devices 16. Alternately, the openings may be accessed using only a single hand, although, the process to access the openings using the single hand may take a longer time period to complete. For example, the process may be completed using only natural or artificial appendages on the single hand.

Thus, a robust electrical current-carrying apparatus packages an increased amount of electronic components that are accessible thorough one of the plurality of openings in the apparatus. The apparatus is a power distribution box in a power distribution system disposed in a vehicle. The removable devices are accessible through the plurality of openings regardless of the number of openings defined in the power distribution box and the removable devices are accessible while at least one wire cable is attached to the power distribution box remains attached in electrical communication with the power distribution box. Having a plurality of openings defined in the power distribution box allows for increased flexibility to access at least one of the plurality of removable electronic devices disposed in the power distribution box. Ensuring the power distribution box is attachable and unattachable from a bracket secured in an engine compartment of the vehicle without using a tool or a special tool saves time and effort to access and service the removable electronic devices. And because only at least one hand of an operator is required during a process to access the removable electronic devices in the power distribution box, the need to procure and provide the tools or special tools is eliminated. The removable electronic devices are accessed by also removing the removable covers that cover the respective plurality of openings. Removing the removable covers also only requires at least one hand of the operator using no tools or special tools. The power distribution box is disposed adjacent an exterior wall of the vehicle in the engine compartment such that the power distribution box is accessible by the operator from a single stationary position adjacent the engine compartment. The removable electronic components adjacent the openings are easily accessed by flippingly movingly or orienting the power distribution box that has been removed from a bracket in the engine compartment to a position where the opening that needs to be accessed visually faces towards the operator. The removable electronic devices adjacent the second opening are only removable fuse electronic devices increasing the likelihood of finding the removable fuse through the second opening in contrast to the first opening to further provide for additional ease in servicing the removable fuse devices. A portion of the housing of the power distribution box is formed of a first dielectric material so that connector ports on the power distribution box may withstand the larger applied mechanical forces to attach the connectors of the wire cables to the power distribution box to provide enhanced reliability for the power distribution box. One electrical circuit arrangement disposed in the power distribution box includes at least one removable relay and one removable fuse configured in a manner that a shared electrical connection between the removable relay and the removable fuse does not require the use of copper circuit board trace while increasing packaging efficiency. The increased packaging efficiency includes the implementation space being optimized by at least a portion of a footprint of one of the removable electronic devices residing within a plane of the other removable device's footprint on an opposing side of the circuit board within the power distribution box. Another electronic circuit arrangement includes a fuse removable device that receives a power source through the fuse removable device that is directly electrically connected to a connector port of the power distribution box. Thus, an output of the removable fuse is directly electrically connected to a double-ended terminal that also serves as a terminal in the connector port which does not require the use of circuit board trace on the circuit board. This fuse electronic circuit arrangement allows for packaging the fuse electronic arrangement in a packaging space of the power distribution box opposing the connector ports so that these fuse removable devices are accessible through the second opening of the power distribution box. This fuse electronic circuit arrangement allows for increased efficiency of packaging the power distribution box in an area underlying at least one of the connector ports. The wire cables are sealingly attached to the first wall of the power distribution box providing for a robust environmental seal of the wire cable to the power distribution box as well as providing a natural, gravity-draining drip-loop mechanization to reduce the possibility for environmental element intrusion in to the power distribution box over the service life of the vehicle.

While this invention has been described in terms of the preferred embodiments thereof, it is not intended to be so limited, but rather only to the extent set forth in the claims that follow. Moreover, the use of the terms first, second, etc. does not denote any order of importance, but rather the terms first, second, etc. are used to distinguish one element from another. Furthermore, the use of the terms a, an, etc. do not denote a limitation of quantity, but rather denote the presence of at least one of the referenced items.

1. An electrical current-carrying apparatus comprising:
a housing defining a first opening and defining a second opening opposite said first opening, the housing being configured to couple to at least one wire cable;
a first plurality of electronic devices disposed within the housing and accessible through the first opening; and
a second plurality of electronic devices disposed within the housing and accessible through the second opening, wherein the at least one wire cable is in electrical communication with at least one electronic device in the first and second plurality of electronic devices, wherein the first plurality of electronic devices is accessible through the first opening and the second plurality of electronic devices is accessible through the second opening while the at least one wire cable remains coupled to the housing.

2. The apparatus according to claim 1, wherein said first opening and said second opening are accessible by only using at least one hand of a human operator.

3. (canceled)

4. The apparatus according to claim 2, wherein the housing further includes,
a first wall,
a second wall, wherein the first wall defines the first opening and the second wall defines the second opening,
a first removable cover configured to cover the first opening, and
a second removable cover configured to cover the second opening, wherein the first removable cover and the second removable cover are releasably attached to the housing.

5. The apparatus according to claim 4, further including,
a bracket for receivably coupling the apparatus, wherein the apparatus comprises a power distribution box disposed in an engine compartment of a vehicle, the vehicle being disposed on a ground surface such that the first wall is remote from the ground surface in a direction generally perpendicular to the ground surface and the second wall is disposed intermediate the first wall and the ground surface.

6. The apparatus according to claim 5, wherein the second plurality of electronic devices consists of removable electronic devices.

7. The apparatus according to claim 6, wherein the second plurality of electronic devices consists of removable fuse electronic devices.

8. The apparatus according to claim 5, wherein the apparatus is disposed in the bracket and the at least one wire cable has sufficient length such that when the apparatus is removed from the bracket, the first opening and the second opening are made accessible to the human operator with the first plurality of electronic devices being made accessible to the human operator when the apparatus is moved relative to the at least one wire cable so that the first opening faces the human operator, and the second plurality of electronic devices being made accessible to the human operator when the apparatus is movingly flipped relative to the first opening about the at least one wire cable so that the second opening faces the human operator.

9. The apparatus according to claim 8, wherein either the first opening or the second opening is accessed using only one human hand of the human operator.

10. The apparatus according to claim 8, wherein the first opening and the second opening are accessed by the human operator disposed in a single stationary position adjacent the engine compartment.

11. The apparatus according to claim 5, wherein the at least one wire cable is attached to at least one connector port disposed along the first wall of the power distribution box.

12. The apparatus according to claim 4, wherein the apparatus further includes,
a printed circuit board disposed in the housing intermediate the first opening and the second opening, wherein said first wall has a parallel, spaced relationship with said second wall.

13. The apparatus according to claim 12, wherein the printed circuit board includes a circuit board trace disposed on the printed circuit board that electrically interconnects at least a portion of the plurality of electronic devices, and at least one electronic circuit arrangement is disposed in the housing that includes at least two removable electronic devices in communication with the printed circuit board and the at least two removable electronic devices include terminals where at least one terminal of one of the at least two removable electronic devices has axial electrical connection with the at least one terminal of another one of the at least two removable electronic devices so that said axial electrical connection of said at least one electronic circuit arrangement communicates with the printed circuit board in a manner that does not use said circuit board trace.

14. The apparatus according to claim 13, wherein the at least two removable electronic devices include device footprints where a first removable device is disposed proximate a first surface of the printed circuit board and a second removable device is disposed proximate a second surface of the printed circuit board, and the second surface opposes the first surface such that a device footprint of the first removable device defines a plane extending in a direction generally perpendicular to the first surface and the second surface so that at least a portion of the device footprint of the second device lies within said plane.

15. The apparatus according to claim 14, wherein a substantial portion of the device footprint of the second removable device lies within said plane.

16. The apparatus according to claim 14, wherein the apparatus includes more than one electronic circuit arrangement to form a group, and the group is in communication with the printed circuit board, the group being disposed in the apparatus adjacent the at least one wire cable to directly electrically connect the group to the at least one wire cable so as to minimize use of said circuit board trace.

17. The apparatus according to claim 1, wherein the apparatus includes a printed circuit board including circuit board traces and the apparatus includes at least one connector port that receivably couples the at least one wire cable, and the second plurality of electronic devices includes removable fuse devices, and the removable fuse devices are included as part of a removable fuse electronic circuit arrangement, the removable fuse electronic circuit arrangement including,
at least one removable fuse device having an input and an output,
a power source in electrical connection with the input, and
an electrically-conductive terminal in electrical connection with the output, wherein the removable fuse electronic circuit arrangement is disposed in a position in the apparatus adjacent the at least one connector port such that the electrically-conductive terminal electrically connects the output to the at least one connector port.

18. The apparatus according to claim 17, wherein the at least one connector port defines a first footprint and the at least one removable fuse device defines a second footprint, wherein the second footprint is at least partially disposed within said first footprint.

19. The apparatus according to claim 17, wherein the electrically-conductive terminal comprises a double-ended terminal in mechanical connection with the printed circuit board having a first end and a second end, said first end of the double-ended terminal being a terminal disposed within a connector port disposed on the apparatus and receiving a mating terminal disposed in a connector attached to the at least one wire cable and the second end of the double-ended terminal receiving the at least one removable fuse device.
